(19) United States
(12) Patent Application Publication
(10) Pub. No.: US 2024/0334622 A1
(43) Pub. Date: Oct. 3, 2024

(54) SPHERE DEVICE WITH MAGNETIC FIELD

(71) Applicant: Ko Wei Ho, Taichung City (TW)

(72) Inventor: Ko Wei Ho, Taichung City (TW)

(21) Appl. No.: 18/126,988

(22) Filed: Mar. 27, 2023

(51) Int. Cl. H05K 5/02; H01F 7/02

(52) U.S. Cl. CPC H05K 5/02; H01F 7/0273

(57) ABSTRACT

A sphere device with a magnetic field is configured to be detected by a magnetic sensor and has a spherical housing, a magnetized core, and a magnet unit. The spherical housing is hollow and is made of a non-magnetic material. The magnetized core is made of a magnetic material and is fixed in the spherical housing. The magnet unit is disposed in the spherical housing and magnetically attached to an external surface of the magnetized core to magnetize the magnetized core. Therefore, a magnetic field around an external surface of the sphere device has less weak region and is easily detected by a magnetic sensor while the sphere device is reaching the magnetic sensor.

### BACKGROUND OF THE INVENTION

### 1. Field of the Invention

The present invention relates to training equipment with a magnetic sensor, and more particularly to a sphere device with magnetic field lines evenly passing through its entire surface adapted to be rolled by a user and detected by the magnetic sensor.

### 2. Description of Related Art

Training equipment for training a user to roll a sphere device such as a training ball to a designated position may comprise a sphere device with a magnetic field and multiple magnetic sensors. When the sphere device is pushed to reach a designated position where one of the magnetic sensors is located, the magnetic field around the external surface of the sphere device will be detected by the magnetic sensor to generate a signal. After receiving the signal, a controller of the training equipment records that the sphere device has reached the designated position.

The sphere device with a magnetic field may be a sphere magnet, or may comprise a spherical housing and at least one magnet disposed in the spherical housing. Each magnet has a north pole and a south pole. The magnetic field is represented by field lines that start at the magnet's north pole and end at the south pole, so the magnetic field around the sphere device is non-uniform with strong and weak regions. The magnetic sensor is only triggered when it detects strong enough magnitude of the magnetic field. So if the sphere device reaches the designated position with a region where the magnitude of the magnetic field is not strong enough, the magnetic sensor is not triggered and thus generates no signal.

To overcome the shortcomings, the present invention tends to provide a sphere device with a magnetic field to mitigate or obviate the aforementioned problems.

### SUMMARY OF THE INVENTION

The main objective of the invention is to provide a sphere device with a magnetic field over its entire external surface. The magnetic field around the entire external surface of the sphere device is strong enough to trigger a magnetic sensor.

The sphere device with a magnetic field is configured to be detected by a magnetic sensor and comprises a spherical housing, a magnetized core, and a magnet unit. The spherical housing is made of a non-magnetic material, is hollow, and has a chamber formed in the spherical housing. The magnetized core is made of a magnetic material and is fixed in the chamber of the spherical housing. The magnet unit generates a persistent magnetic field, is disposed in the chamber of the spherical housing, and is magnetically attached to a side of an external surface of the magnetized core to magnetize the magnetized core.

Other objects, advantages and novel features of the invention will become more apparent from the following detailed description when taken in conjunction with the accompanying drawings.

### BRIEF DESCRIPTION OF THE DRAWINGS

FIG. 1 is a cross sectional side view of a first embodiment of a sphere device with a magnetic field in accordance with the present invention;

FIG. 2 is an exploded perspective view of the sphere device in FIG. 1;

FIG. 3 is a side view in partial section of the sphere device in FIG. 1;

FIG. 4 is an operational side view of the sphere device in FIGS. 1 and shows the sphere device rolling;

FIG. 5 is an operational perspective view of the sphere device in FIG. 1 and shows the sphere device rolling on training equipment;

FIG. 6 is an exploded perspective view of a second embodiment of a sphere device with a magnetic field in accordance with the present invention; and

FIG. 7 is an exploded perspective view of a third embodiment of a sphere device with a magnetic field in accordance with the present invention.

### DETAILED DESCRIPTION OF PREFERRED EMBODIMENT

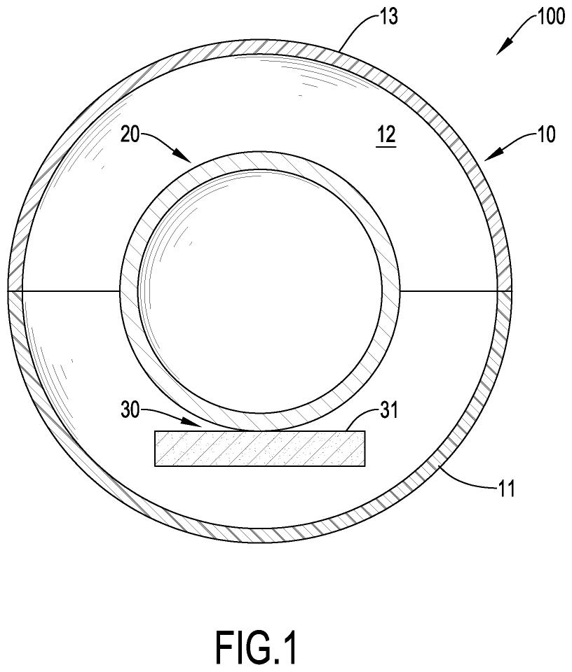

With reference to FIGS. 1 to 3, a first embodiment of a sphere device 100 with a magnetic field in accordance with the present invention comprises a spherical housing 10, a magnetized core 20, and a magnet unit 30.

The spherical housing 10 is hollow and has a chamber 12 formed therein. The spherical housing 10 is made of a non-magnetic material that cannot be magnetized. The spherical housing 10 may include multiple housing bodies 11, 13 combined with each other.

The magnetized core 20 is disposed in the chamber 12 of the spherical housing 10 and is made of a magnetic material. The magnetized core 20 may be a magnetic object of any shape. The magnetized core 20 may be made of ferromagnetic metal such as iron that has good permeability and low cost. Preferably, the magnetized core 20 is hollow and spherical.

The magnet unit 30 includes a permanent magnet and generates a persistent magnetic field, is disposed in the chamber 12 of the spherical housing 10, and is magnetically attached to a side of an external surface of the magnetized core 20 to magnetize the magnetized core 20.

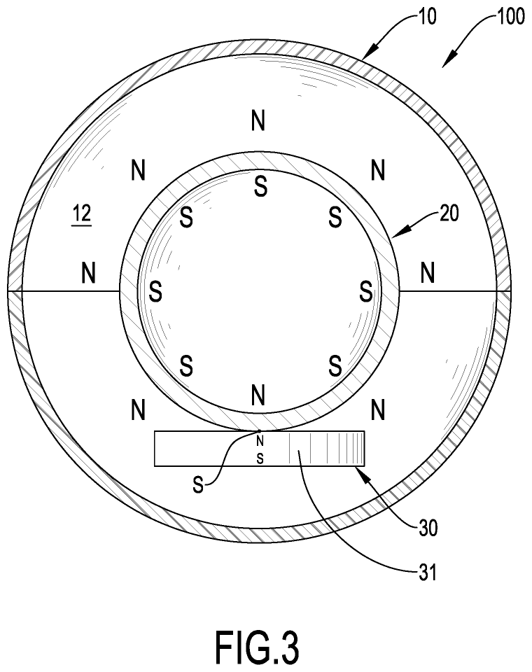

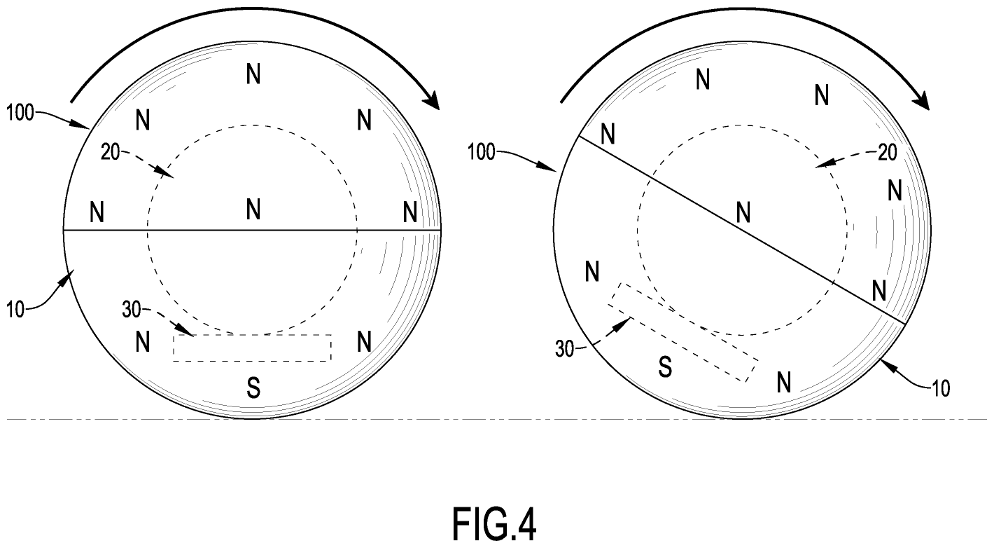

With reference to FIGS. 3 and 4, the magnet unit 30 has a first magnetic pole facing toward the magnetized core 20 and a second magnetic pole facing away from the magnetized core 20. In this embodiment, the first magnetic pole is a north pole N and the second magnetic pole is a south pole S. The magnetic field lines outside of the magnet unit 30 begin at the first magnetic pole and terminate at the second magnetic pole. When the magnet unit 30 magnetizes and is magnetically attached to the magnetized core 20, the poles of magnetic domains within the magnetized core 20 are aligned with magnetic field lines generated by the magnet unit 30. So only a region of the external surface of the magnetized core 20 that contacts the first magnetic pole (north pole N) of the magnet unit 30 becomes a second magnetic pole (south pole S). The other regions, of the external surface of the magnetized core 20, located far from the first magnetic pole of the magnet unit 30 become first magnetic poles (north poles N). Accordingly, only a region of the external surface of the spherical housing 10 that corresponds to the second magnetic pole (south pole S) of the magnet unit 30 in position becomes the second magnetic pole (south pole S), and the other regions of the external surface of the spherical housing 10 that correspond to the first magnetic pole (north pole N) of the magnetized core 20 in positions become the first magnetic poles (north pole N). Most regions of the external surface of the spherical housing 10 are the first magnetic poles (north pole N). Fewest regions of the external surface of the spherical housing 10 are the second magnetic poles (south pole S). In the present invention, magnetic field lines may evenly pass through the external surface of the spherical housing 10. Therefore, even when the sphere device 100 rolls, the most regions of the external surface of the spherical housing 10 can be detected by magnetic sensors.

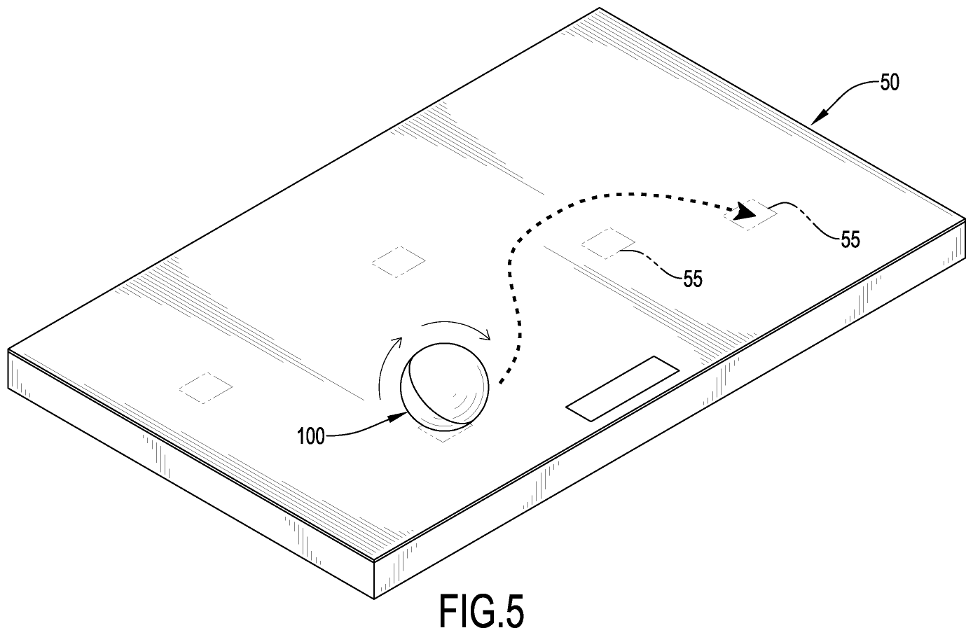

With reference to FIGS. 3 to 5, the sphere device 100 in accordance with the present invention is suitable for training equipment 50 as shown in FIG. 5. The training equipment 50 comprises multiple magnetic sensors 55 respectively deployed at multiple designated positons. The sphere device 100 can be detected by one of the magnetic sensors 55 when the sphere device 100 reaches a corresponding one of the designated positions of the magnetic sensor 55. When the magnetic sensor 55 detects the magnetic field around the sphere device 100, the magnetic sensor 55 transmits a signal to a controller of the training equipment 50. The controller records that the sphere device 100 has arrived at the designated position and may assign another designated position for the sphere device 100 to reach. With most of the surface area of the external surface of the spherical housing 10 representing the first magnetic pole N, the magnetic field lines evenly pass through the external surface of the spherical housing 10. When the sphere device 100 rolls, the most regions of the external surface of the spherical housing 10 can be easily detected by magnetic sensors.

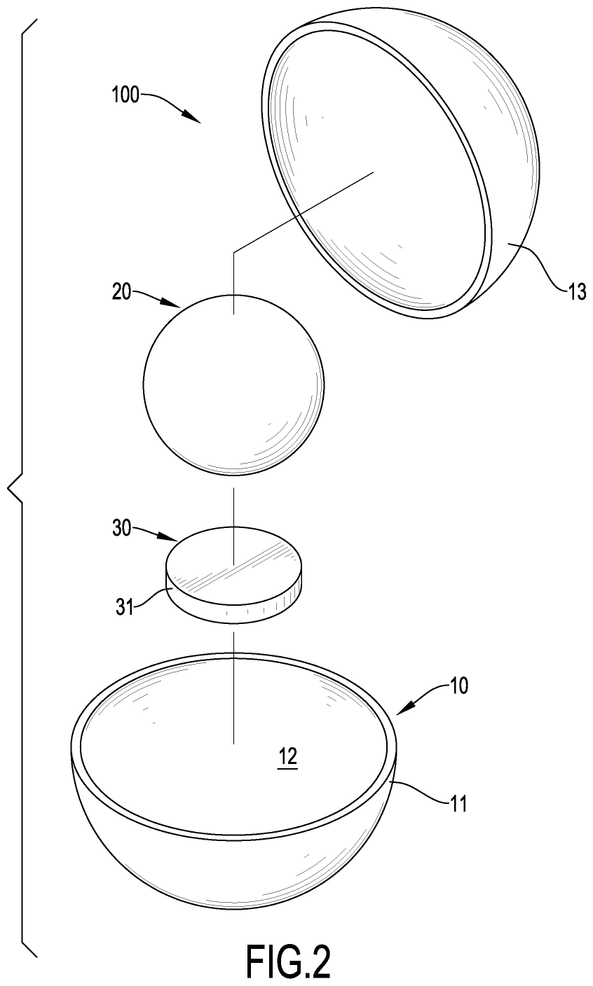

With reference to FIG. 2, the magnetized core 20 with the magnet unit 30 may be fixed in the chamber 12 of the spherical housing 10 by any means. The magnetized core 20 and the magnet unit 30 may be fixed in the chamber 12 of the spherical housing 10 by adhering, e.g. hot-melt adhesive or glue.

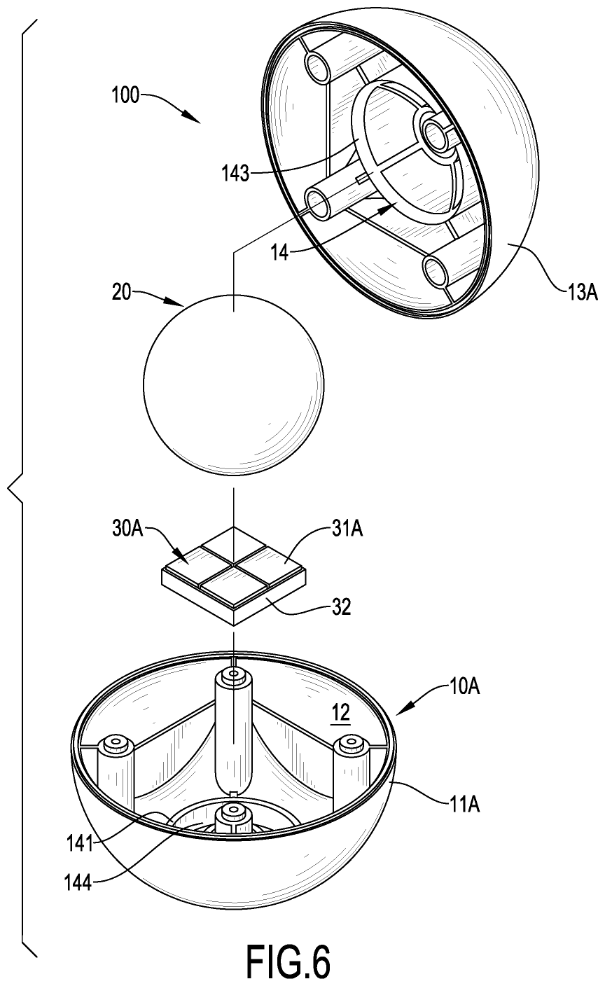

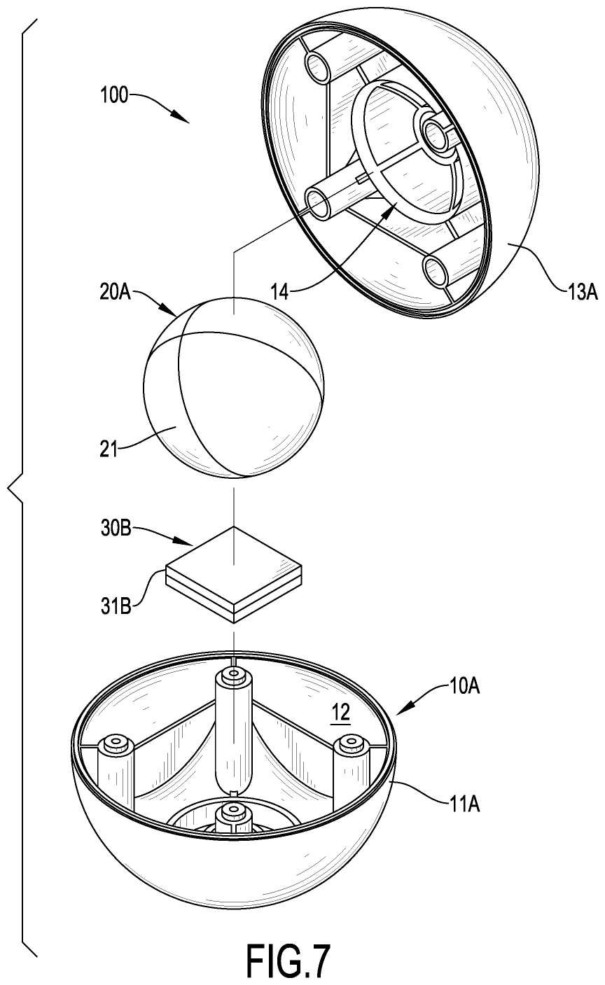

With reference to FIGS. 6 and 7, the spherical housing 10A may include a supporting structure 14 formed in the chamber 12 of the spherical housing 10A to fix or support the magnetized core 20, 20A and the magnet unit 30A, 30B magnetically attached to the magnetized core 20, 20A. The supporting structure 14 may include at least one supporting rib 141 formed in the chamber 12 and protruding from an internal surface of the spherical housing 10A to support the magnetized core 20, 20A and the magnet unit 30A, 30B. The supporting structure 14 may include a core holder 143 to support the magnetized core 20 and a magnet cavity 144 for receiving the magnet unit 30A, 30B.

With reference to Fig.6, the two housing bodies 11A, 13A of the spherical housing 10A are formed by molding. Each of the two housing bodies 11A, 13A may include at least one supporting rib 141, so the magnetized core and the magnet unit 30A can be supported by the supporting ribs 141 of the two housing bodies 11A, 13A from opposite two sides of the magnetized core 20. The core holder 143 may be formed at one of the two housing bodies 11A, and the magnet cavity 144 may be formed at the other one of the two housing bodies 13A. The magnetized core 20 and the magnet unit 30A can be fixed in the chamber 12 of the spherical housing 10A with a hot-melt adhesive. The two housing bodies 11A, 13A can be combined with each other via ultrasonic bonding, adhesive, or fasteners. In other embodiment, a filler made of a non-magnetic material may be filled into the chamber of the spherical housing to fill up the space between the spherical housing, hereby fixing the magnetized core and the magnet unit in position.

With reference to FIGS. 2, 6, and 7, the magnet unit 30 may include a permanent magnet 31 as shown in FIG. 2. The magnet unit 30A, 30B May include multiple permanent magnets 31A, 31B as shown in FIGS. 6 and 7. In addition, the magnet unit 30A may include a casing 32 to carry the multiple permanent magnets 31A as shown in FIG. 6. The permanent magnet 31, 31A, 31B may each be a neodymium magnet (NdFeB magnet), which has a stronger magnetic force to magnetize the magnetized core 20, 20A. The magnetized core 20 may include one core body as shown in FIGS. 2 and 6. The magnetized core 20 may include multiple core bodies 21 assembled to one another as shown in FIG. 7.The spherical housing 10, 10A may have a diameter of 72 millimeters. The two housing bodies 11, 11A, 13, 13A may be made of plastic materials, e.g. Acrylonitrile Butadiene Styrene (ABS). The magnetized core 20, 20A may have a diameter of 40 millimeters and may be a hollow iron ball to decrease a weight thereof. The magnet unit 30, 30A, 30B is magnetically attached to a side of the external surface of the magnetized core 20 to entirely magnetize the magnetized core 20. The magnet unit 30 as shown in FIG. 2 may have a diameter of 30 millimeters and a thickness of 5 millimeters. After the magnetized core 20, 20A and the magnet unit 30, 30A, 30B are disposed in and connected to one of the two housing bodies 11A, 13A, the two housing bodies 11A, 13A are combined with each other via ultrasonic bonding. The sphere device 100 may have a total weight around 160 grams and the diameter of 72 millimeters, which is similar to a field hockey ball. The sphere device 100 is included in the training equipment 50 with the magnetic sensors 55 as shown in FIG. 5. The sphere device 100 is configured to be detected by the magnetic sensors 55.

In the preset invention, the magnetized core is not limited to a hollow ball or a solid ball. A space may be formed between or may not be formed between the spherical housing, the magnetized core, and the magnet unit.

What is claimed is:

1. A sphere device with a magnetic field configured to be detected by a magnetic sensor, the sphere device comprising:
a spherical housing made of a non-magnetic material, being hollow, and having a chamber formed in the spherical housing;
a magnetized core made of a magnetic material and fixed in the chamber of the spherical housing; and
a magnet unit generating a persistent magnetic field, disposed in the chamber of the spherical housing, and magnetically attached to a side of an external surface of the magnetized core to magnetize the magnetized core.

2. The sphere device as claimed in claim 1, wherein the magnet unit has a first magnetic pole facing toward the magnetized core and a second magnetic pole facing away from the magnetized core.

3. The sphere device as claimed in claim 2, wherein the magnetized core is hollow.

4. The sphere device as claimed in claim 2, wherein the magnetized core is hollow and spherical.

5. The sphere device as claimed in claim 2, wherein the magnet unit includes a permanent magnet.

6. The sphere device as claimed in claim 2, wherein the magnet unit includes multiple permanent magnets.

7. The sphere device as claimed in claim 2, wherein the spherical housing includes multiple housing bodies combined with each other.

8. The sphere device as claimed in claim 2, wherein
the spherical housing includes a supporting structure formed in the chamber of the spherical housing; and
the supporting structure includes at least one supporting rib formed in the chamber to support the magnetized core and the magnet unit.

9. The sphere device as claimed in claim 2, wherein
the spherical housing includes a supporting structure formed in the chamber of the spherical housing; and
the supporting structure includes a core holder to support the magnetized core and a magnet cavity to receive the magnet unit.

10. The sphere device as claimed in claim 2, wherein
the spherical housing includes two housing bodies combined with each other and a supporting structure formed in the chamber of the spherical housing;
the supporting structure includes a core holder and a magnet cavity;
the core holder is formed at one of the two housing bodies to support the magnetized core; and
the magnet cavity is formed at the other one of the two housing bodies to receive the magnet unit.
